(19) United States
(12) Patent Application Publication
(10) Pub. No.: US 2026/0011350 A1
(43) Pub. Date: Jan. 8, 2026

(54) THREE-DIMENSIONAL MEMORY ARRAY, MEMORY, AND ELECTRONIC DEVICE

(71) Applicant: HUAWEI TECHNOLOGIES CO., LTD., Shenzhen (CN)

(72) Inventors: Kailiang Huang, Shenzhen (CN); Weiliang Jing, Shanghai (CN); Zhaogui Wang, Shanghai (CN); Ying Sun, Shenzhen (CN); Zhengbo Wang, Shenzhen (CN)

(73) Assignee: HUAWEI TECHNOLOGIES CO., LTD., Shenzhen (CN)

(21) Appl. No.: 19/329,929

(22) Filed: Sep. 16, 2025

Related U.S. Application Data
(63) Continuation of application No. PCT/CN2023/138469, filed on Dec. 13, 2023.

(30) Foreign Application Priority Data
Mar. 17, 2023 (CN) 202310297345.7

(51) Int. Cl. G11C 5/06; G11C 11/4096

(52) U.S. Cl. CPC G11C 5/063; G11C 11/4096

(57) ABSTRACT

The present disclosure relates to three-dimensional memory arrays, memories, and electronic devices. Each memory cell in an example three-dimensional memory array includes a first transistor and a second transistor. The second transistor used as a read transistor may use a dual-gate structure. One gate is electrically connected to the first transistor used as a write transistor, and the other gate may be electrically connected to a read word line. One of a source and a drain of the second transistor is grounded. In addition, in a process structure of the memory cell, each film layer structure of the first transistor and each film layer structure of the second transistor are integrated into at least four stacked insulation dielectric layers.

### CROSS-REFERENCE TO RELATED APPLICATIONS

This application is a continuation of International Application No. PCT/CN2023/138469, filed on Dec. 13, 2023, which claims priority to Chinese Patent Application No. 202310297345.7, filed on Mar. 17, 2023. The disclosures of the aforementioned applications are hereby incorporated by reference in their entireties.

### TECHNICAL FIELD

This application relates to the field of semiconductor storage technologies, and in particular, to a three-dimensional memory array, a memory including the three-dimensional memory array, a method for forming the three-dimensional memory array, and an electronic device including the memory.

### BACKGROUND

In a computing system, for example, a dynamic random access memory (DRAM) may be used as an internal memory structure to temporarily store operation data of a central processing unit (CPU) and exchange data with an external memory like a hard disk, and is a very important part of the computing system.

With development of a memory with higher density and larger bandwidth, memory cells of different structures emerge, for example, a 2T0C memory cell, a 1T1C memory cell, or a 2TnC memory cell. Herein, T represents a transistor, and C represents a capacitor.

FIG. 1 is a circuit diagram of a memory cell in a DRAM in a related technology. The memory cell includes a write transistor Tw and a read transistor Tr. A gate of the write transistor Tw is electrically connected to a write word line (WWL). One of a source and a drain of the write transistor Tw is electrically connected to a write bit line (WBL), and the other one of the source and the drain of the write transistor Tw is electrically connected to a gate of the read transistor Tr. One of a source and a drain of the read transistor Tr is electrically connected to a read word line (RWL), and the other one of the source and the drain of the read transistor Tr is electrically connected to a read bit line (RBL).

For the 2T0C memory cell shown in FIG. 1, in a “write” operation, the write word line WWL is used to control the write transistor Tw to be turned on, and potential of the write bit line WBL is transferred to the gate of the read transistor Tr, potential of the gate of the read transistor Tr is synchronized with the write bit line WBL to implement writing of “0” and “1”, and then the write word line WWL controls the write transistor Tw to be turned off. In a “read” operation, a storage status needs to be determined based on only a current of the read transistor Tr.

A reading manner of the memory cell is current reading. In a reading process, a serious voltage drop (IR drop) exists on the read word line RWL. Consequently, during process manufacturing, a process length of the read word line RWL is limited, and it is difficult to prepare a large-capacity three-dimensional memory array.

### SUMMARY

This disclosure provides a three-dimensional memory array, a memory including the three-dimensional memory array, a method for forming the three-dimensional memory array, and an electronic device including the memory. A main objective is to provide a memory array that can alleviate a voltage drop (IR drop) problem on a read word line RWL and implement three-dimensional stacking.

To achieve the foregoing objectives, the following technical solutions are used in embodiments of this disclosure.

According to a first aspect, this disclosure provides a three-dimensional memory array. For example, the three-dimensional memory array may be used in a dynamic random access memory (DRAM).

The three-dimensional memory array includes a substrate and a plurality of memory arrays formed on the substrate, and the plurality of memory arrays are stacked in a direction perpendicular to the substrate. Each memory array includes a plurality of electrode lines and a plurality of memory cells. Each memory cell includes a first transistor and a second transistor. The second transistor is a dual-gate transistor. A first gate of the second transistor is electrically connected to a first electrode of the first transistor. Other electrodes of the first transistor and the second transistor are electrically connected to the plurality of electrode lines separately. For example, a first electrode of the second transistor is grounded, a second electrode is electrically connected to a read bit line RBL, and a second gate of the second transistor is electrically connected to a read word line RWL. The first electrode, a second electrode, and a channel layer of the first transistor are located at a first metal layer, and a gate of the first transistor is located at another metal layer. The first electrode, the second electrode, and a channel layer of the second transistor are located at a second metal layer, the first gate and the second gate of the second transistor are located at other metal layers, and the first gate and the second gate are located at different metal layers. The first electrode is one of a source and a drain, and the second electrode is the other of the source and the drain.

In the three-dimensional memory array in this disclosure, the first transistor in the memory cell may be used as a write transistor, and the second transistor may be used as a read transistor. In addition, the read transistor is a dual-gate transistor. In this case, compared with a read transistor of a single-gate structure, when the memory cell performs a “read” operation, basically no current flows through a gate of the read transistor, so that a voltage drop (IR drop) can be mitigated, and a length of an electrode line is basically not limited. In addition, in a process structure, the source, the drain, and the channel of the first transistor are located at a same metal layer, and the gate is located at another metal layer. Similarly, the source, the drain, and the channel of the second transistor are located at a same metal layer, and the two gates are located at different metal layers. In this case, when the memory array is manufactured, a plurality of insulation dielectric layers may be sequentially stacked, and then these stacked insulation dielectric layer structures are processed, so that a plurality of memory arrays perpendicular to the substrate can be processed at the same time, and a three-dimensional stacked memory array structure is implemented.

Therefore, the memory array provided in this disclosure can not only alleviate a voltage drop (IR drop) of the read word line, but also implement stacking of three-dimensional memory arrays, to increase a storage capacity.

In a possible implementation, the first gate of the second transistor is located at the first metal layer, and shares a same electrode with the first electrode of the first transistor.

In a possible implementation, the gate of the first transistor is located at a third metal layer, and the third metal layer is stacked on a side that is of the first metal layer and that is away from the second metal layer.

In an implementation, the gate of the first transistor is located on one side of the channel layer of the first transistor, and the first electrode of the second transistor is located on the other side of the channel layer of the first transistor. An orthographic projection of the gate of the first transistor on the substrate at least partially overlaps an orthographic projection of the first electrode of the second transistor on the substrate.

In the process structure of the memory cell, the first transistor and the second transistor are arranged in a direction parallel to the substrate, and an orthographic projection of a partial structure of the first transistor on the substrate coincides with an orthographic projection of a partial structure of the second transistor on the substrate. In this case, a size of each memory cell in a Z direction (a direction perpendicular to the substrate) may be reduced, and a size of each memory cell in an X direction or a Y direction (directions parallel to the substrate) may also be reduced, to reduce an area occupied by each memory cell. For example, in this disclosure, an area occupied by each memory cell may be reduced to 2 F×4 F.

In a possible implementation, the second gate of the second transistor is located at a fourth metal layer, and the fourth metal layer is stacked on a side that is of the second metal layer and that is away from the first metal layer.

In an implementation, the first gate of the second transistor is located on one side of the channel layer of the second transistor, and the second gate of the second transistor is located on the other side of the channel layer of the second transistor. An orthographic projection of the first gate on the substrate at least partially overlaps an orthographic projection of the second gate on the substrate.

In this way, an area of each memory cell can also be reduced, to improve storage density.

In an implementation, the plurality of electrode lines include a first electrode line and a second electrode line. The first electrode line is electrically connected to the gate of the first transistor, and the second electrode line is electrically connected to the second gate of the second transistor. The first electrode line and the gate of the first transistor are located at a same metal layer. The second electrode line and the second gate of the second transistor are located at a same metal layer. The first electrode line is parallel to the second electrode line. The first electrode line is electrically connected to gates of two adjacent first transistors. The second electrode line is electrically connected to second gates of two adjacent second transistors.

In an implementation, the plurality of electrode lines include a third electrode line and a fourth electrode line. The third electrode line is electrically connected to the second electrode of the first transistor, and the fourth electrode line is electrically connected to the second electrode of the second transistor. Both the third electrode line and the fourth electrode line extend in a direction perpendicular to the substrate. The third electrode line is electrically connected to second electrodes of first transistors in two adjacent memory arrays. The fourth electrode line is electrically connected to second electrodes of second transistors in two adjacent memory arrays.

In the memory array, the first electrode line and the second electrode line extend in a direction parallel to the substrate, and the third electrode line and the fourth electrode line extend in a direction perpendicular to the substrate. A voltage is applied to the four electrode lines, to select a to-be-read/written memory cell.

In an implementation, the plurality of electrode lines include a ground lead, the ground lead is located at the second metal layer, and the ground lead is electrically connected to first electrodes of two adjacent second transistors.

In the memory cell provided in this embodiment of this disclosure, because one of the source and the drain of the second transistor used as the read transistor is grounded, the ground electrode needs to be electrically connected to a peripheral ground structure. In the implementation structure, a plurality of ground electrodes arranged in a same direction may be electrically connected through the ground lead, and then electrically connected to the peripheral ground structure.

In a possible implementation, the first electrode of the second transistor is isolated from the channel layer of the first transistor by a dielectric layer.

The dielectric layer is used to isolate the channel layer of the first transistor from the source (or the drain) that is of the second transistor and that is used for grounding.

In an implementation, the dielectric layer includes a gate dielectric layer, and the gate dielectric layer is stacked between the channel layer of the first transistor and the first electrode of the second transistor.

In an example, the gate of the first transistor and the channel layer of the first transistor are also isolated by the gate dielectric layer, and the channel layer of the first transistor and the first electrode of the second transistor are also isolated by the gate dielectric layer. In a process flow, the two gate dielectric layers may be formed at the same time. In this way, the process flow is not complex.

In an implementation, the dielectric layer includes a gate dielectric layer and an insulation dielectric layer. The gate dielectric layer and the insulation dielectric layer are stacked between the channel layer of the first transistor and the first electrode of the second transistor, and the insulation dielectric layer is closer to the first electrode of the second transistor than the gate dielectric layer.

The insulation dielectric layer is added between the gate dielectric layer and the first electrode of the second transistor, so that the channel layer can be protected from being damaged due to excessive etching during manufacturing.

In an implementation, in the first transistor or the second transistor, a contact transition layer is formed between interfaces in which the channel layer is in ohmic contact with the first electrode, and/or between interfaces in which the channel layer is in ohmic contact with the second electrode.

The contact transition layer that can reduce contact resistance is disposed between interfaces in which the first electrode or the second electrode is in ohmic contact with the channel layer, to increase a channel current and improve read/write performance of the memory cell.

In a possible implementation, a metal layer is formed between the channel layer and the first electrode, and the metal layer forms the contact transition layer.

The metal layer is used as the contact transition layer. In a manufacturing process, after the channel layer is manufactured, the metal layer is deposited at an end that is of the channel layer and that is close to the source/drain, to manufacture the contact transition layer.

Alternatively, in a possible implementation, a doped conductive part is formed at an end that is of the channel layer and that is close to the first electrode, a doping concentration of the doped conductive part is greater than a doping concentration of the channel layer, and the doped conductive part forms the contact transition layer.

In this embodiment, a semiconductor is heavily doped to form the contact transition layer used to reduce the resistance.

In a possible implementation, the contact transition layer is of a strip structure parallel to the substrate, and is stacked between the electrode and the channel layer.

In an implementation, the contact transition layer formed between the channel layer and the first electrode includes a first part, a second part, and a third part. Both the first part and the second part are parallel to the substrate, the third part is connected to the first part and the second part to form a structure having a concave cavity, the first electrode is disposed in the concave cavity, and the third part is in contact with the channel layer.

In an implementation, the plurality of electrode lines and the plurality of memory cells are all formed on the substrate through a back end of line.

Both the first transistor and the second transistor are manufactured through the back end of line, and the controller may be manufactured through a front end of line. The controller may include one or more circuits of a decoder, a driver, a timing controller, a buffer, or an input/output driver, and may further include another functional circuit. The controller may control the first electrode line, the second electrode line, the third electrode line, and the fourth electrode line in this embodiment of this disclosure. After the front end of line (FEOL) is completed, an interconnection line and the memory array are manufactured through the back end of line (BEOL), so that circuit density per unit area can be improved, thereby improving storage performance per unit area.

In an implementation, the three-dimensional memory array is a DRAM three-dimensional memory array.

In this way, the memory cell is understood as a 2T0C memory cell in the DRAM memory array.

In a possible implementation, when the memory cell is understood as a 2T0C memory cell in the DRAM memory array, the first electrode line is a write word line, the second electrode line is a read word line, the third electrode line is a write bit line, and the fourth electrode line is a read bit line.

According to a second aspect, this disclosure further provides a memory. The memory includes a controller and the memory array in any one of the foregoing implementations. The controller is electrically connected to the memory array, and the controller is configured to control read/write of the memory array.

In the memory provided in this disclosure, because the memory includes the memory array in the foregoing implementation, in each memory cell of the memory array, a read transistor is of a dual-gate structure. One gate is electrically connected to a write transistor, and the other gate is electrically connected to a read word line. In this way, when a read operation is performed, no current flows through the gate of the read transistor, to mitigate a voltage drop of the read word line. In this way, a process length of the read word line is not limited, and one read word line may be electrically connected to more memory cells, to increase a storage capacity.

In addition, according to the process structure, the memory array may be stacked in a direction perpendicular to a substrate, to implement three-dimensional stacking, implement high-density integration, and increase a storage capacity.

In a possible implementation, the memory array and the controller are integrated into a same chip, and the chip is disposed on a base board.

In a possible implementation, the memory array is integrated into a first chip, the controller is integrated into a second chip, and each of the first chip and the second chip is disposed on a base board via an electrical connection structure.

In a possible implementation, the memory array is integrated into the first chip, the controller is integrated into the second chip, and the first chip and the second chip are stacked and integrated on the base board.

According to a third aspect, this disclosure further provides an electronic device, including a processor and the memory in any one of the foregoing implementations. The processor is electrically connected to the memory, and the memory is configured to store data generated by the processor.

The electronic device provided in this embodiment of this disclosure includes the memory in any one of the foregoing implementations. Therefore, the electronic device provided in this embodiment of this disclosure and the memory in the foregoing technical solution can resolve a same technical problem and implement same expected effect.

According to a fourth aspect, this disclosure further provides a method for forming a three-dimensional memory array. The forming method includes:
sequentially stacking a plurality of insulation dielectric layers on a substrate; and
performing patterning processing on the plurality of insulation dielectric layers to form a plurality of metal layers, and forming, in the plurality of metal layers, a plurality of memory arrays stacked in a direction perpendicular to a substrate.

Each memory array includes a plurality of electrode lines and a plurality of memory cells. Each memory cell includes a first transistor and a second transistor. The second transistor is a dual-gate transistor. A first gate of the second transistor is electrically connected to a first electrode of the first transistor. Other electrodes of the first transistor and the second transistor are electrically connected to the plurality of electrode lines separately.

The first electrode, a second electrode, and a channel layer of the first transistor are located at a first metal layer in the plurality of metal layers, and a gate of the first transistor is located at another metal layer.

A first electrode, a second electrode, and a channel layer of the second transistor are located at a second metal layer in the plurality of metal layers, the first gate and a second gate of the second transistor are located at other metal layers, and the first gate and the second gate are located at different metal layers.

One of a source and a drain is the first electrode, and the other of the source and the drain is the second electrode.

In the method for forming the three-dimensional memory array provided in this disclosure, the plurality of insulation dielectric layers are stacked on the substrate, and the plurality of insulation dielectric layers are processed to obtain the plurality of memory arrays, so as to obtain a plurality of three-dimensional memory arrays perpendicular to the substrate.

In a possible implementation, sequentially stacking the plurality of insulation dielectric layers on the substrate includes:
sequentially stacking a first insulation dielectric layer, a second insulation dielectric layer, a third insulation dielectric layer, and a fourth insulation dielectric layer on the substrate; and
separately performing patterning processing on the first insulation dielectric layer, the second insulation dielectric layer, the third insulation dielectric layer, and the fourth insulation dielectric layer, to form the gate of the first transistor in the first insulation dielectric layer, form the first electrode, the second electrode, and the channel layer of the first transistor and the first gate of the second transistor in the second insulation dielectric layer, form the first electrode, the second electrode, and the channel layer of the second transistor in the third insulation dielectric layer, and form the second gate of the second transistor in the fourth insulation dielectric layer.

That is, a memory array structure may be obtained by using four stacked insulation dielectric layers.

In a possible implementation, forming the channel layer of the first transistor in the second insulation dielectric layer includes:
etching the second insulation dielectric layer to form a groove in the second insulation dielectric layer, form a gate dielectric layer on an inner wall surface of the groove, and form the channel layer of the first transistor in the groove having the gate dielectric layer.

In a possible implementation, after forming the channel layer of the first transistor, the forming method further includes:
doping an end that is of the channel layer and that is used to be in contact with the first electrode or the second electrode, to form a doped conductive part, where a doping concentration of the doped conductive part is greater than a doping concentration of the channel layer, and the doped conductive part is configured to form a contact transition layer at which the doped conductive part is in ohmic contact with the first electrode or the second electrode.

For example, the end of the channel layer may be doped in an ion injection manner, to form a heavily doped region.

Ohmic contact resistance between the channel layer and the source/drain can be reduced by using the heavily doped region formed through ion implantation.

In a possible implementation, after forming the channel layer of the first transistor, the forming method further includes: forming a metal layer at an end that is of the channel layer and that is in contact with the first electrode or the second electrode, where the metal layer is used to form a contact transition layer in ohmic contact with the first electrode or the second electrode.

In this implementation, the metal layer is deposited at the end of the channel layer, to obtain a suppression layer structure that reduces contact resistance.

In a possible implementation, when the plurality of electrode lines are formed, the method includes:
forming a first electrode line in the first insulation dielectric layer, and forming a second electrode line in the fourth insulation dielectric layer, where the first electrode line is parallel to the second electrode line, the first electrode line is electrically connected to gates of two adjacent first transistors, and the second electrode line is electrically connected to second gates of two adjacent second transistors.

In a possible implementation, forming the plurality of electrode lines includes:
forming a third electrode line and a fourth electrode line that are both perpendicular to the substrate.

The third electrode line is electrically connected to second electrodes of first transistors in two adjacent memory arrays.

The fourth electrode line is electrically connected to second electrodes of second transistors in two adjacent memory arrays.

In a possible implementation, forming the plurality of electrode lines includes:
forming a ground lead in the third insulation dielectric layer, where the ground lead is electrically connected to first electrodes of two adjacent second transistors.

The ground lead is disposed to lead out a ground electrode of the second transistor in each memory array, so as to be electrically connected to a peripheral ground structure.

In a possible implementation, forming the gate of the first transistor in the first insulation dielectric layer, and forming the first electrode of the second transistor in the third insulation dielectric layer includes:
forming the gate of the first transistor on one side of two opposite sides of the channel layer of the first transistor, and forming the first electrode of the second transistor on the other side of the two opposite sides of the channel layer of the first transistor.

In a possible implementation, forming the first gate of the second transistor in the second insulation dielectric layer, and forming the second gate of the second transistor in the fourth insulation dielectric layer includes:
using the first electrode of the prepared first transistor as the first gate of the second transistor; and
in the fourth insulation medium, forming the second gate of the second transistor on a side that is of the channel layer of the second transistor and that is away from the first gate of the second transistor.

A memory cell manufactured through this process occupies a small area. For example, an area occupied by each memory cell may be reduced to 2 F×4 F. In this way, more memory cells can be integrated in a unit area, thereby improving storage density.

### BRIEF DESCRIPTION OF DRAWINGS

FIG. 1 is a circuit diagram of a 2T0C memory cell;

FIG. 2 is a circuit diagram of an electronic device according to an embodiment of this disclosure;

FIG. 3 is a circuit diagram of a memory according to an embodiment of this disclosure;

FIG. 4A is a diagram of a packaging structure of a memory array and a controller according to an embodiment of this disclosure;

FIG. 4B is a diagram of a packaging structure of a memory array and a controller according to an embodiment of this disclosure;

FIG. 4C is a diagram of a packaging structure of a memory array and a controller according to an embodiment of this disclosure;

FIG. 5 is a diagram of a three-dimensional structure of a memory according to an embodiment of this disclosure;

FIG. 6 is a simple circuit diagram of a memory according to an embodiment of this disclosure;

FIG. 7 is a circuit diagram of a memory cell in a memory according to an embodiment of this disclosure;

FIG. 8 is a circuit diagram of a memory array in a memory according to an embodiment of this disclosure;

FIG. 9 is a diagram of a process structure of a memory cell according to an embodiment of this disclosure;

FIG. 10 is a diagram of a process structure of a memory cell according to an embodiment of this disclosure;

FIG. 11 is a diagram of a process structure of a memory cell according to an embodiment of this disclosure;

FIG. 12 is a diagram of a three-dimensional process structure of a three-dimensional stacked memory array according to an embodiment of this disclosure;

FIG. 13 is a diagram of a process structure in an X-Z plane of a three-dimensional stacked memory array according to an embodiment of this disclosure;

FIG. 14 is a diagram of a process structure in an X-Y plane of a three-dimensional stacked memory array according to an embodiment of this disclosure;

FIG. 15 is a top view of a memory cell according to an embodiment of this disclosure;

FIG. 16 is a diagram of a process structure of a memory cell according to an embodiment of this disclosure;

FIG. 17A and FIG. 17B are diagrams of process structures corresponding to some steps in a preparation process of a memory cell according to an embodiment of this disclosure;

FIG. 18A and FIG. 18B are diagrams of process structures corresponding to some steps in a preparation process of a memory cell according to an embodiment of this disclosure;

FIG. 19 is a diagram of a process structure of a memory cell according to an embodiment of this disclosure;

FIG. 20 is a diagram of a process structure of a memory cell according to an embodiment of this disclosure;

FIG. 21 is a diagram of a process structure of a memory cell according to an embodiment of this disclosure;

FIG. 22 is a block flowchart of a method for forming a memory array according to an embodiment of this disclosure;

FIG. 23A to FIG. 23H are diagrams of corresponding structures obtained after steps are completed in a preparation process of a memory array chip according to embodiments of this disclosure; and

FIG. 24 is a diagram of a corresponding structure obtained when a contact transition layer is added in a preparation process of a memory array chip according to an embodiment of this disclosure.

### REFERENCE NUMERALS

100: electronic device;
210: SOC; 211: disclosure processor; 212: GPU; 213: second memory; 205: bus; 220: first memory; 230: communication chip; 240: power management chip;
300: memory;
31: memory array;
32: control circuit;
400, 401, 402, 403, 404, and 405: memory cells;
first transistor Tw;
101: first electrode; 102: second electrode; 103: channel layer; 104: first gate; 105: gate dielectric layer;
second transistor Tr;
201: first electrode; 202: second electrode; 203: channel layer; 204: first gate; 205:
second gate; 206: gate dielectric layer;
41, 42, and 43: contact transition layers;
431: first part; 432: second part; 433: third part.

### Description of Embodiments

The following describes content in embodiments of this disclosure in detail with reference to accompanying drawings.

An embodiment of this disclosure provides an electronic device. FIG. 2 is a block diagram of a circuit in an electronic device 100 according to an embodiment of this disclosure. The electronic device 100 may be a terminal device, for example, a mobile phone, a tablet computer, a smart band, a personal computer (PC), a server, a workstation, or the like.

As shown in FIG. 2, the electronic device 100 may include a bus 205 and a system on chip (SOC) 210 connected to the bus 205. The SOC 210 may be configured to process data, for example, process data of an disclosure, process image data, and cache temporary data. In an implementation, the SOC 210 may include an disclosure processor (disclosure processor, AP) 211 configured to process an disclosure, a graphics processing unit (GPU) 212 configured to process image data, and a first random access memory (RAM) 213 configured to cache high-speed data. The first RAM 213 may be a static random access memory (SRAM), an embedded flash (eflash), or the like. The AP 211, the GPU 212, and the first RAM 213 may be integrated into one die, or may be separately disposed in a plurality of dies.

As shown in FIG. 2, the electronic device 100 may further include a second RAM 220 connected to the SOC 210 through the bus 205. The second RAM 220 may be a dynamic random access memory (DRAM). The second RAM 220 may be configured to store volatile data, for example, temporary data generated by the SOC 210. A storage capacity of the second RAM 220 is usually greater than that of the first RAM 213, but a read speed of the second RAM 220 is usually slower than that of the first RAM 213.

In addition, the electronic device 100 may further include a communication chip 230 and a power management chip 240 that are connected to the SOC 210 through the bus 205. The communication chip 230 may be configured to process a protocol stack, or perform processing such as amplification and filtering on an analog radio frequency signal, or implement the foregoing functions at the same time. The power management chip 240 may be configured to supply power to another chip. In an implementation, the SOC 210 and the second RAM 220 may be packaged in a packaging structure, for example, 2.5D (dimension) or 3D packaging is used, to obtain a faster inter-chip data transmission rate.

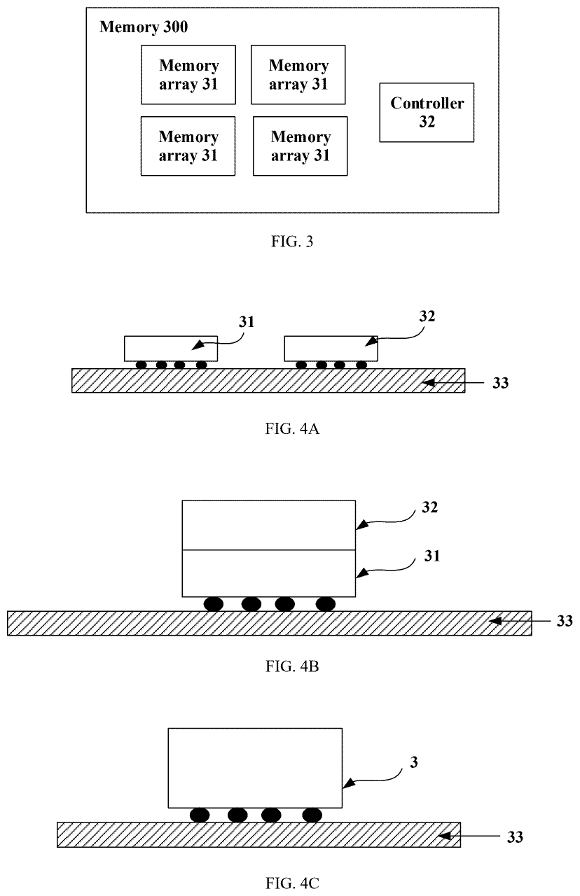

FIG. 3 is a block diagram of a circuit of a memory 300 that can be used in an electronic device according to an embodiment of this disclosure. In an implementation, the memory 300 may be the first RAM 213 or the second RAM 220 shown in FIG. 2. An disclosure scenario of the memory 300 in this disclosure is not limited.

As shown in FIG. 3, the memory 300 includes a memory array 31 and a controller 32 configured to access the memory array 31. The controller 32 is configured to control a read/write operation on the memory array 31.

The memory array 31 and the controller 32 shown in FIG. 3 have a plurality of implementable packaging structures. For example, the following provides several implementable packaging structures.

FIG. 4A shows a packaging structure of the memory array 31 and the controller 32 according to an embodiment of this disclosure. To be specific, the memory array 31 and the controller 32 are two chips independent of each other, and the memory array 31 and the controller 32 are separately integrated on a base board 33. For example, the memory array 31 and the controller 32 may be electrically conducted through a metal wire disposed on the base board 33. In this structure, because the memory array 31 and the controller 32 are two independent chips, the memory array 31 may be referred to as a stand-alone memory.

FIG. 4B shows another packaging structure of the memory array 31 and the controller 32 according to an embodiment of this disclosure. In this structure, similar to FIG. 4A, the memory array 31 and the controller 32 are two chips independent of each other. Therefore, the memory array 31 may also be referred to as a stand-alone memory. Different from FIG. 4A, in FIG. 4B, the memory array 31 and the controller 32 are stacked. For example, the memory array 31 and the controller 32 may be connected through a through silicon via (TSV) or a redistribution layer (RDL).

FIG. 4C shows still another packaging structure of the memory array 31 and the controller 32 according to an embodiment of this disclosure. In this example structure, the memory array 31 and the controller 32 are integrated into a same chip 3, and the chip 3 is integrated on the base board 33. Therefore, the memory array 31 may be referred to as an embedded memory.

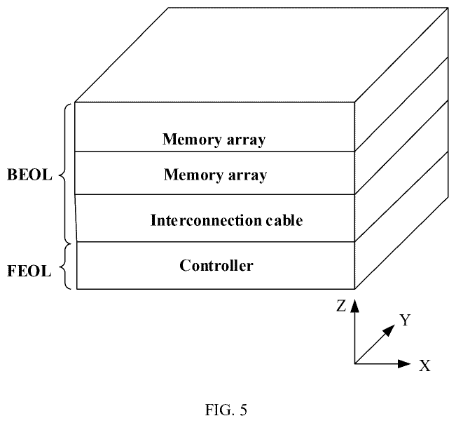

In the structure shown in FIG. 4C, as shown in FIG. 5, the controller 32 may be integrated on a substrate through a front end of line (FEOL) process, and an interconnection cable and the memory array are integrated on the controller 32 through a back end of line (BEOL) process. The controller herein may be used to generate a control signal. The control signal may be a read/write control signal used to control a read/write operation on data in the memory array. In addition, the controller herein may also include an analog circuit part, for example, a sense amplifier.

In addition, as shown in FIG. 5, the memory array 31 may be one memory array, or may be a plurality of memory arrays stacked in a Z direction perpendicular to the substrate shown in FIG. 5. When the memory array 31 includes two or more memory arrays, such a memory may be referred to as a three-dimensional integrated memory structure, to increase a storage capacity.

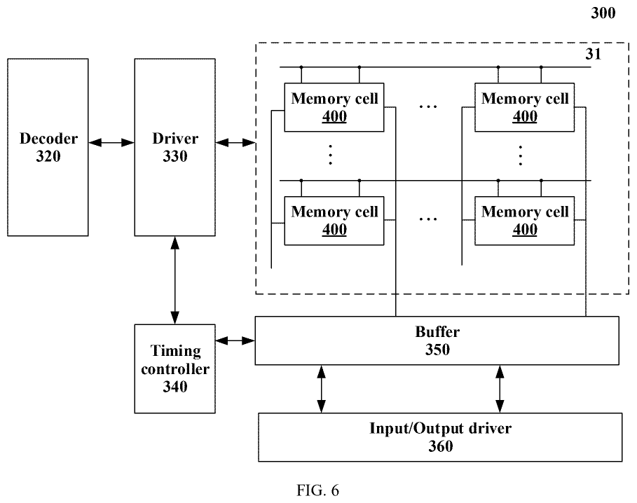

In an implementation, the memory array 31 in the memory may include a plurality of memory cells 400 arranged in an array shown in FIG. 6, and each memory cell 400 may be configured to store 1-bit (bit) or multi-bit data. The memory array 31 may further include signal lines such as a word line (WL) and a bit line (BL). Each memory cell 400 is electrically connected to a corresponding word line WL and a corresponding bit line BL. Different memory cells 400 may be electrically connected through WLs and BLs. One or more of the WLs and the BLs are used to select a memory cell 400 to be read from/written into in the memory array by receiving a control level output by a control circuit, to implement a data read/write operation.

The controller 32 in the memory may include one or more circuit structures of a decoder 320, a driver 330, a timing controller 340, a buffer 350, or an input/output driver 360 shown in FIG. 6.

In a structure of the memory 300 shown in FIG. 6, the decoder 320 is configured to perform decoding based on a received address, to determine a memory cell 400 to be accessed. The driver 330 is configured to control a level of a signal line based on a decoding result generated by the decoder 320, to implement access to a specified memory cell 400. The buffer 350 is configured to buffer read data, for example, may buffer the data in a first-in first-out (FIFO) manner. The timing controller 340 is configured to control timing of the buffer 350, and control the driver 330 to drive a signal line in the memory array 310. The input/output driver 360 is configured to drive a transmission signal, for example, drive a received data signal and drive a data signal to be sent, so that the data signals can be transmitted over long distances.

The memory array 310, the decoder 320, the driver 330, the timing controller 340, the buffer 350, and the input/output driver 360 may be integrated into one chip, or may be integrated into a plurality of chips.

The memory 300 in embodiments of this disclosure may be a dynamic random access memory (DRAM). For example, the memory 300 may be a DRAM including a 2T0C memory cell. A gain-cell memory including a 2T0C memory cell structure can implement a nanosecond-level read/write speed and a millisecond-level storage time, and an occupied area of the gain-cell memory is only one third of that of a static random access memory (SRAM) because the gain-cell memory is widely used.

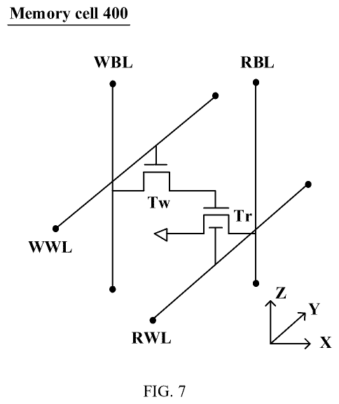

FIG. 7 is a circuit diagram of a memory cell 400 according to an embodiment of this disclosure. As shown in FIG. 7, the memory cell 400 is of a 2T0C gain-cell memory cell structure. To be specific, one memory cell 400 includes one first transistor Tw (which may also be referred to as a write transistor) and one second transistor Tr (which may also be referred to as a read transistor) that are electrically connected. For example, the first transistor Tw and the second transistor Tr each may be a thin film transistor (TFT) structure.

The first transistor Tw may be a transistor of a single-gate structure, and the second transistor Tr may be a transistor of a dual-gate structure.

A first gate of the second transistor Tr is electrically connected to a first electrode of the first transistor Tw, and other electrodes of the first transistor Tw and the second transistor Tr are electrically connected to a plurality of electrode lines separately.

For example, as shown in FIG. 7, a gate of the first transistor Tw is electrically connected to a write word line (WWL), a second electrode of the first transistor Tw is electrically connected to a write bit line (WBL), and the first electrode of the first transistor Tw is electrically connected to the first gate of the second transistor Tr.

A first electrode of the second transistor Tr is grounded, a second electrode of the second transistor Tr is electrically connected to a read bit line (RBL), and a second gate of the second transistor Tr is electrically connected to a read word line (RWL).

One of a first electrode and a second electrode of the transistor in this embodiment of this disclosure is a source, and the other is a drain.

The following separately describes a write operation process and a read operation process of the 2T0C memory cell 400 shown in FIG. 7.

In the write operation process, a voltage on the read bit line RBL is 0, and the second transistor Tr does not operate; and a first write word line control signal is provided for the write word line WWL, and the first transistor Tw is controlled to be turned on through the first write word line control signal. When first logical information, for example, “0”, is written, a first write bit line control signal is provided for the write bit line WBL, and the first write bit line control signal is written into a node SN via the first transistor Tw. When second logical information, for example, “1”, is written, a second write bit line control signal is provided for the write bit line WBL, and the second write bit line control signal is written into the node SN via the first transistor Tw, to write the logical information.

In the read operation process, a second write word line control signal is provided for the write word line WWL, and the second write word line control signal controls the write transistor Tw to be turned off, and the read word line control signal is provided for the read word line RWL, and logical information stored in the memory cell is determined based on a current on the read bit line RBL. When the node stores the first write bit line control signal, the first write bit line control signal can control the second transistor Tr to be turned on. Therefore, when the read word line RWL (or the write bit line WBL) provides the read word line control signal, the read word line RWL (or the write bit line WBL) charges the read bit line RBL via the second transistor Tr, and a voltage on the read bit line RBL increases. In this way, when it is detected that a current on the read bit line RBL is large, it may be read that logical information “0” is stored in the memory cell. When the node stores the second write bit line control signal, the second transistor Tr may be controlled to be turned off through the second write bit line control signal. Therefore, when the read word line RWL (or the write bit line WBL) provides the read word line control signal, the read word line RWL (or the write bit line WBL) does not charge the read bit line RBL via the second transistor Tr, and the read bit line RBL maintains a voltage of 0 V. In this way, when it is detected that a current on the read bit line RBL is small, it may be read that logical information “1” is stored in the memory cell.

The memory cells shown in FIG. 7 are arranged in two dimensions, to obtain the memory array shown in FIG. 8.

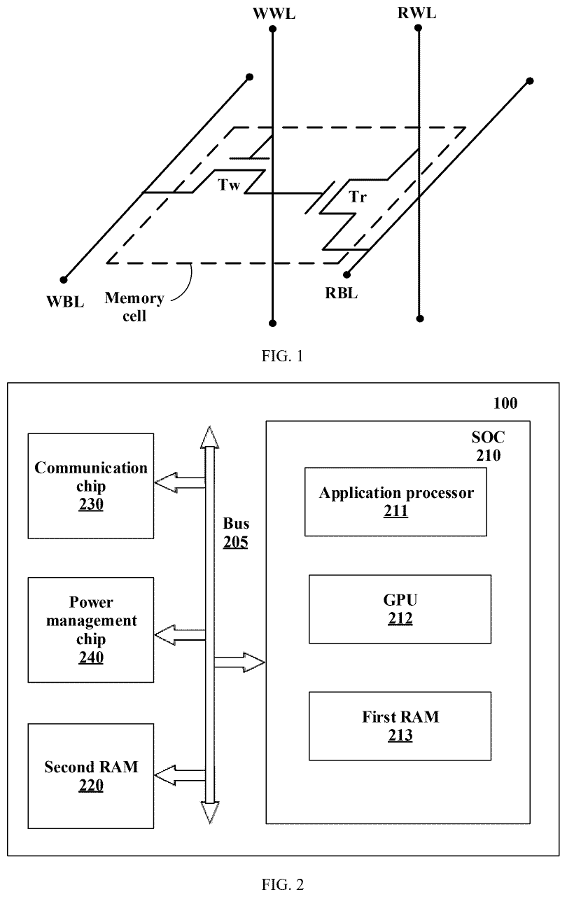

As shown in FIG. 7 and FIG. 8, in the 2T0C memory cell provided in embodiments of this disclosure, the second transistor Tr used as the read transistor includes two gates, and one of the gates is electrically connected to the read word line RWL. One of a source and a drain of the second transistor Tr is grounded, and the other is electrically connected to the read bit line RBL. This is different from FIG. 1 in which one of the source and the drain of the second transistor Tr is electrically connected to the read word line RWL, and the other is electrically connected to the read bit line RBL. In this way, for example, in FIG. 8, when the read operation is performed, no current flows through the gate of the read transistor, a read word line RWL 1 electrically connected to a gate of a memory cell 401, a gate of a memory cell 402, and a gate of a memory cell 403 basically has no voltage drop from left to right. Therefore, in a manufacturing process, a length of the read bit line RBL 1 is basically not limited by the voltage drop, and a longer process length may be designed, so that more memory cells are electrically connected, and a storage capacity is increased via more memory cells.

On the basis of relieving the voltage drop (IR drop) of the memory cell, an embodiment of this disclosure further provides a process structure of a memory cell. The process structure can implement three-dimensional stacking of the memory cell, to produce a three-dimensional memory cell with a large capacity.

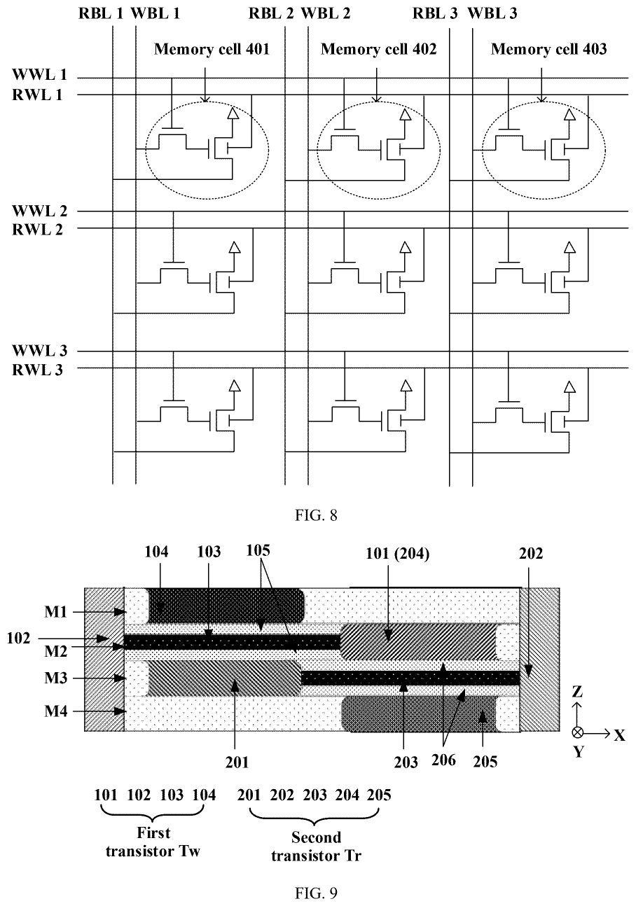

FIG. 9 is a diagram of a process structure of a memory cell, and the diagram of the process structure is a diagram obtained after the memory cell is cut in a direction perpendicular to a substrate. The memory cell includes a first transistor Tw and a second transistor Tr that are electrically connected. The first transistor Tw may be of a single-gate structure, and the second transistor Tr may be of a dual-gate structure. In addition, film layer structures of the first transistor Tw and the second transistor Tr are integrated into a metal layer M1, a metal layer M2, a metal layer M3, and a metal layer M4 that are sequentially stacked. The metal layer M1, the metal layer M2, the metal layer M3, and the metal layer M4 that are stacked are sequentially arranged in the direction perpendicular to the substrate.

Still refer to FIG. 9. A first electrode 101, a second electrode 102, and a channel layer 103 of the first transistor Tw are formed in the metal layer M2, the first electrode 101 and the second electrode 102 are arranged in a direction parallel to the substrate, and the channel layer 103 is formed between the first electrode 101 and the second electrode 102. A channel formed in this way may be referred to as a horizontal channel parallel to the substrate.

In addition, a first electrode 201, a second electrode 202, and a channel layer 203 of the second transistor Tr are formed in the metal layer M3, the first electrode 201 and the second electrode 202 are also arranged in a direction parallel to the substrate, and the channel layer 203 is formed between the first electrode 201 and the second electrode 202. A channel formed in this way is similar to the first transistor Tw, and may also be referred to as a horizontal channel parallel to the substrate.

The metal layer M2 and the metal layer M3 may be metal layers adjacent to each other.

A metal layer at which a gate 104 of the first transistor Tw is located is at a metal layer different from the metal layer M2.

A first gate 204 and a second gate 205 of the second transistor Tr are also located at other metal layers different from the metal layer M3. The “different from” herein may be understood as being located at different metal layers. For example, the gate 104 of the first transistor Tw is not located at the metal layer M2.

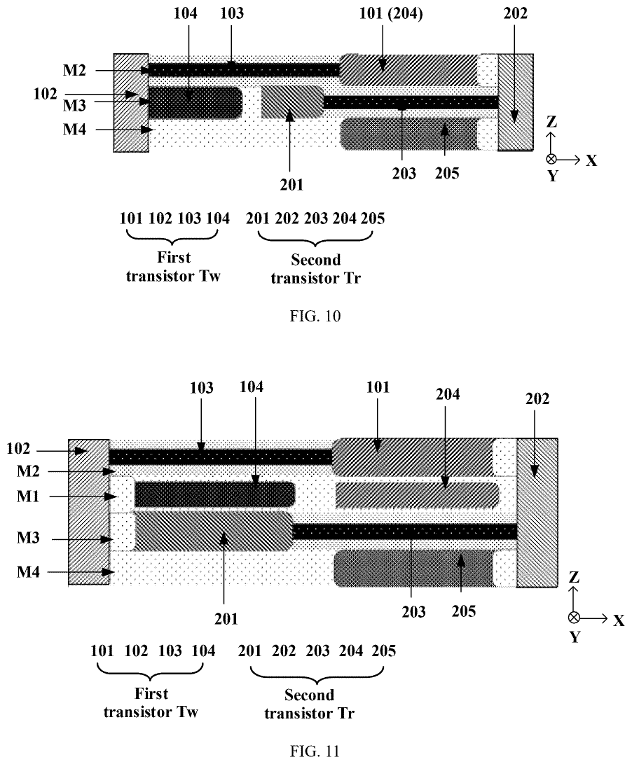

In addition, the first gate 204 and the second gate 205 of the second transistor Tr are located at different metal layers. In addition to FIG. 9, embodiments of this disclosure further provide several different process structures of the first transistor Tw and the second transistor Tr, for example, FIG. 10 and FIG. 11.

For example, in FIG. 9, in the first transistor Tw, the gate 104 is formed in the metal layer M1, the metal layer M1 is located on a side that is of the metal layer M2 and that is away from the metal layer M3, and the gate 104 is isolated from the channel layer 103 by a gate dielectric layer 105. In the second transistor Tr, the first gate 204 is formed in the metal layer M2, and the second gate 205 is formed in the metal layer M4. The first gate 204 is isolated from the channel layer 203 by a gate dielectric layer 206, and the second gate 205 is also isolated from the channel layer 203 by the gate dielectric layer 206.

In the circuit structure, the first electrode of the first transistor Tw is electrically connected to one gate of the second transistor Tr. In some process structures, to simplify a process, for example, in the structure shown in FIG. 9, the first electrode 101 of the first transistor Tw may not only be used as one of a source and a drain of the first transistor Tw, but also be used as the first gate 204 of the second transistor Tr. In other words, the first electrode 101 of the first transistor Tw and the first gate 204 of the second transistor Tr share a same electrode. To be specific, an electrode is manufactured to be used as the first electrode 101 of the first transistor Tw and the first gate 204 of the second transistor Tr.

For another example, in FIG. 10, structures shown in FIG. 10 and FIG. 9 are the same in that the first electrode 101, the second electrode 102, and the channel layer 103 of the first transistor Tw are formed in the metal layer M2, and the first electrode 201, the second electrode 202, and the channel layer 203 of the second transistor Tr are formed in the metal layer M3. The structures shown in FIG. 10 and FIG. 9 are different in that the gate 104 of the first transistor Tw is also located at the metal layer M3 in FIG. 10. To be specific, three stacked metal layers are used to integrate film layer structures of the two transistors in FIG. 10, while four stacked metal layers are used to integrate film layer structures of the two transistors in FIG. 9.

For still another example, in FIG. 11, structures shown in FIG. 11, FIG. 9, and FIG. 10 are the same in that the first electrode 101, the second electrode 102, and the channel layer 103 of the first transistor Tw are formed in the metal layer M2, and the first electrode 201, the second electrode 202, and the channel layer 203 of the second transistor Tr are formed in the metal layer M3. However, in FIG. 11, the metal layer M1 is located between the metal layer M2 and the metal M3, the gate 104 of the first transistor Tw is located at the metal layer M1, and the first gate 204 of the second transistor Tr is also located at the metal layer M1, in instead of a case in which the first gate 204 of the second transistor Tr and the first electrode 101 of the first transistor Tw share a same electrode with in FIG. 9.

With reference to the memory cells of different process structures shown in FIG. 9 to FIG. 11, at least three metal layers are used to integrate film layer structures of the two transistors.

From a perspective of a process method, for example, when the memory cell shown in FIG. 9 is prepared, four insulation dielectric layers may be stacked on the substrate, and the memory cell is prepared by performing processes such as photolithography and deposition on these insulation dielectric layers. According to this process, if more memory arrays need to be prepared, more dielectric layers may be stacked on the substrate, to simultaneously prepare a plurality of memory arrays perpendicular to the substrate, so as to implement three-dimensional stacking of memory cells and expand a storage capacity.

A specific process method that can be implemented is described subsequently, and how to simultaneously prepare a plurality of memory arrays through one process is described with reference to the process method. Details are not described herein.

Still refer to FIG. 9. To reduce an area occupied by the memory cell, the gate 104 of the first transistor Tw and the first electrode 201 that is of the second transistor Tr and that is used for grounding are disposed opposite to each other on two sides of the channel layer 103 of the first transistor Tw, that is, the gate 104 of the first transistor Tw is located on one side of an upper side and a lower side, and the first electrode 201 of the second transistor Tr is located on the other side of the upper side and the lower side. It may also be considered that an orthographic projection of the gate 104 on the substrate at least partially overlaps an orthographic projection of the first electrode 201 on the substrate.

In this way, an orthographic projection of the first transistor Tw on the substrate partially overlaps an orthographic projection of the second transistor Tr on the substrate. In addition, in the second transistor Tr, the first gate 204 is located on one side of an upper side and a lower side of the channel layer 203, and the second gate 205 is located on the other side of the upper side and the lower side of the channel layer 203. The first gate 204 may be referred to as a top gate, and the second gate 205 may be referred to as a bottom gate. In addition, because the first electrode 101 of the first transistor Tw and the first gate 204 of the second transistor Tr share a same electrode layer structure, an orthographic projection of the first transistor Tw in a direction perpendicular to the substrate also partially overlaps an orthographic projection of the second transistor Tr in the direction perpendicular to the substrate. In this way, space occupied by each memory cell can be reduced as much as possible, so that more memory cells are stacked on the substrate in a three-dimensional manner, and a storage capacity is increased, which matches high-speed development of a controller, and avoids a problem that a “memory wall” occurs because a read/write speed cannot keep up with an operation speed of the processor.

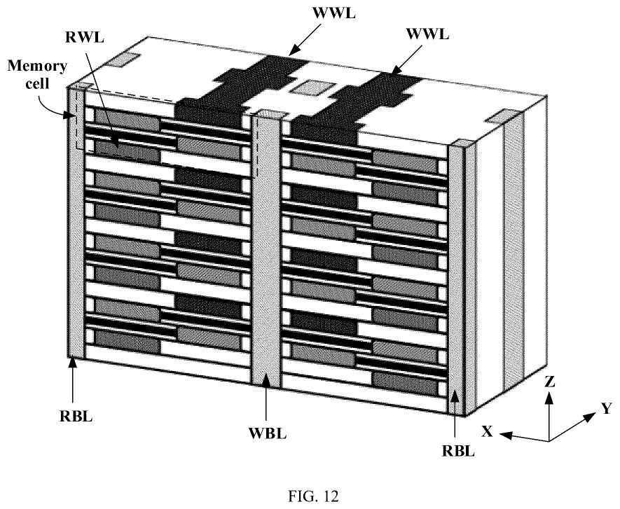

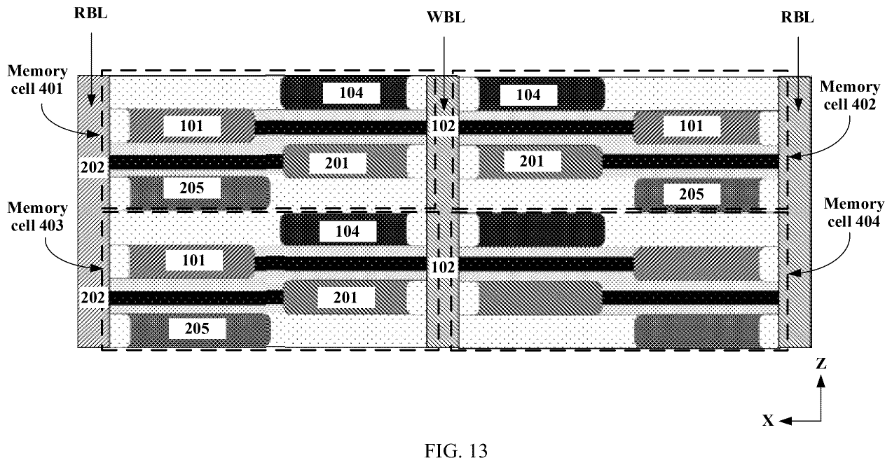

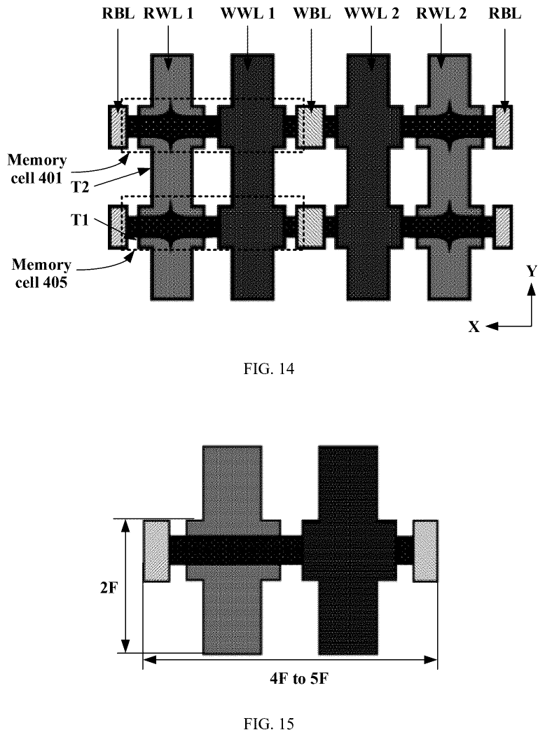

FIG. 12 is a diagram of a process structure of a three-dimensional memory array obtained by performing three-dimensional stacking on the memory cells shown in FIG. 9. FIG. 13 is a diagram of a process structure of an X-Y two-dimensional plane in FIG. 12, and FIG. 14 is a diagram of a process structure of an X-Z two-dimensional plane in FIG. 12.

Refer to the circuit diagram shown in FIG. 7 again. The memory array further includes the write word line WWL, the write bit line WBL, the read bit line RBL, and the read word line RWL. Therefore, in the process structures shown in FIG. 13 and FIG. 14, the write bit line WBL electrically connected to the second electrode 102 of the first transistor Tw and the read bit line RBL electrically connected to the second electrode 202 of the second transistor Tr may both extend in a Z direction perpendicular to the substrate, the write bit line WBL is electrically connected to second electrodes 102 of first transistors Tw in two adjacent memory arrays, and the read bit line RBL is electrically connected to second electrodes 202 of second transistors Tr in two adjacent memory arrays. For example, in FIG. 13, the write bit line WBL is electrically connected to a second electrode 102 of a first transistor Tw of a memory cell 401 and a second electrode 102 of a first transistor Tw of a memory cell 403 that are arranged vertically, and the read bit line RBL is electrically connected to a second electrode 202 of a second transistor Tr of the memory cell 401 and a second electrode 202 of a second transistor Tr of the memory cell 403 that are arranged vertically.

Still refer to FIG. 13. In a same memory array, two adjacent memory cells may share a same write bit line WBL. For example, the memory cell 401 and a memory cell 402 in FIG. 13 may share a same write bit line WBL. Alternatively, in some examples, two adjacent memory cells may share a same read bit line RBL.

In addition, a process structure of the memory cell 401 and a process structure of the memory cell 402 may be symmetrically disposed with respect to the write bit line WBL.

Refer to FIG. 14. In the diagram of the process structure according to an embodiment of this disclosure, both the write word line WWL and the read word line RWL extend in directions parallel to the substrate, and the extension directions are parallel. For example, in FIG. 14, both the write word line WWL and the read word line RWL extend in a Y direction parallel to the substrate. Each write word line WWL is electrically connected to gates 104 of a plurality of first transistors Tw arranged in the Y direction, and each read word line RWL is electrically connected to second gates 205 of a plurality of second transistors Tr arranged in the Y direction. For example, a write word line WWL 1 is electrically connected to a gate 104 of a first transistor Tw of a memory cell 401 and a gate 104 of a first transistor Tw of a memory cell 405 that are arranged in the Y direction, and a read word line RWL 1 is electrically connected to a second gate 205 of a second transistor Tr of the memory cell 401 and a second gate 205 of a second transistor Tr of the memory cell 405 that are arranged in the Y direction.

The write word line WWL and the read word line RWL that extend in a direction parallel to the substrate have a plurality of shapes. For example, in FIG. 14, in an extension direction of the read word line RWL, a first part T1 and a second part T2 are included. A width size of the first part T1 is greater than a width size of the second part T2, and the width size herein may be understood as a size in a direction perpendicular to the extension direction.

The first part T1 is a part configured to form the second gate of the second transistor Tr, and the second part T2 is a part configured to connect second gates of two adjacent second transistors Tr.

A shape of the write word line WWL may be similar to that of the read word line RWL, or may include a part with a wide width and a part with a narrow width.

In addition, in the memory cell provided in this embodiment of this disclosure, one of the source and the drain of the read transistor is grounded. For example, the first electrode 201 of the second transistor Tr in FIG. 7 is grounded. To ensure that first electrodes 201 of second transistors Tr in a same memory array are electrically connected to a peripheral grounded structure, first electrodes 201 of the plurality of second transistors Tr arranged in the Y direction are electrically connected together through a ground lead located at a metal layer, which is similar to the write word line WWL and the read word line RWL shown in FIG. 14.

Based on the process structure of the memory array shown above, as shown in FIG. 15, each memory cell and a write word line WWL, a write bit line WBL, a read bit line RBL, and a read word line RWL that correspondingly electrically connected to the memory cell occupy a length of approximately 4 F to 5 F in an X-Y plane parallel to the substrate, and occupy a width of approximately 2 F. In other words, the memory cell occupies a small area, and more memory cells are easily integrated per unit area, to increase a storage capacity.

The following are diagrams of process structures of some other memory cells provided in embodiments of this disclosure.

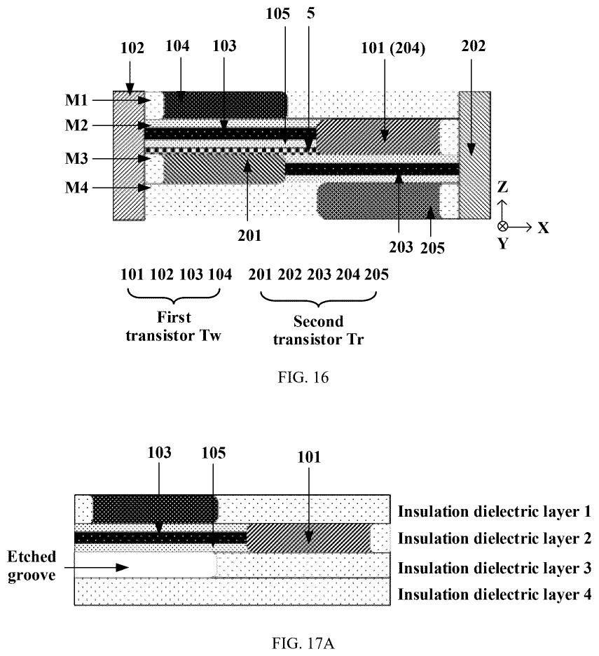

As shown in FIG. 16, like FIG. 9, FIG. 16 also shows a process structure of a memory cell obtained after the memory cell is cut in a direction perpendicular to the substrate. In FIG. 9, the first electrode 201 of the second transistor Tr is located at the metal layer M3, and the channel layer 103 of the first transistor Tw is located at the metal layer M2 adjacent to the metal layer M3. To avoid an electrical connection between the first electrode 201 of the second transistor Tr and the channel layer 103 of the first transistor Tw, the gate dielectric layer 105 is disposed between interfaces in which the channel layer 103 is in contact with the first electrode 201, that is, the channel layer 103 and the first electrode 201 are electrically isolated through the gate dielectric layer 105 stacked between the channel layer 103 and the first electrode 201.

In some processes, the dielectric layer of the metal layer M2 may be first etched to form a concave cavity, and then a gate dielectric layer 105 between the first gate 104 and the channel layer 103, and a gate dielectric layer 105 between the first electrode 201 and the channel layer 103 are formed through deposition on an inner wall surface of the concave cavity.

The memory cell shown in FIG. 16 differs from the memory cell shown in FIG. 9 in that the gate dielectric layer 105 and an insulation dielectric layer 5 are disposed between the interfaces in which the channel layer 103 is in contact with the first electrode 201. The gate dielectric layer 105 and the insulation dielectric layer 5 are stacked between the channel layer 103 and the first electrode 201, and the insulation dielectric layer 5 is closer to the first electrode 201 than the gate dielectric layer 105.

FIG. 17A and FIG. 17B are diagrams of some process structures for preparing a memory cell. Refer to FIG. 17A. After the first electrode 101 and the channel layer 103 of the first transistor Tw are prepared in an insulation dielectric layer 2, in some process flows, a groove needs to be etched in an insulation dielectric layer 3 adjacent to the insulation dielectric layer 2, to form the first electrode 201 of the second transistor Tr in FIG. 17B. When an etching groove process shown in FIG. 17A is performed, the gate dielectric layer 105 may be etched, and the channel layer 103 may be damaged. This reduces a product yield.

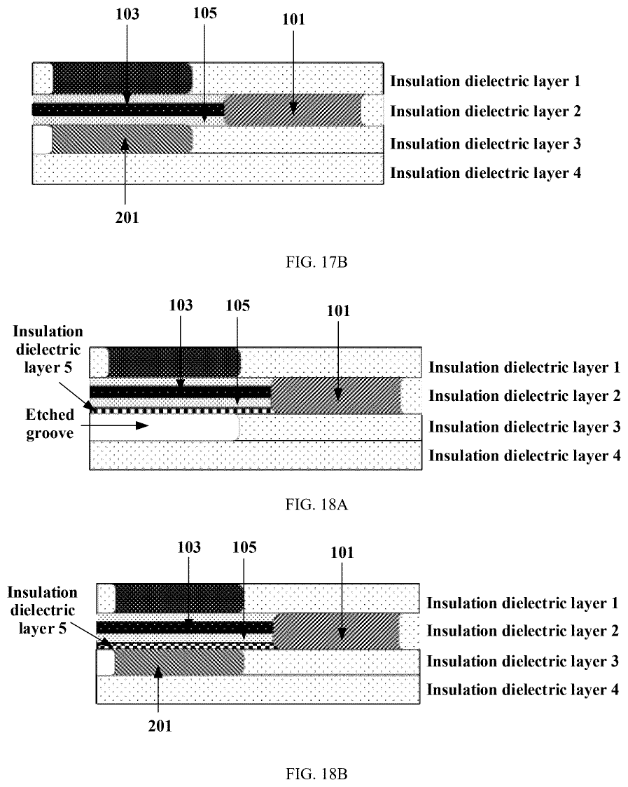

FIG. 18A and FIG. 18B are diagrams of some process structures for preparing a memory cell. Refer to FIG. 18A. Compared with the memory cell in FIG. 17A, the memory cell in FIG. 18A not only includes an insulation dielectric layer 1, the insulation dielectric layer 2, the insulation dielectric layer 3, and an insulation dielectric layer 4 that are stacked, but also includes an insulation dielectric layer 5 stacked between the insulation dielectric layer 2 and the insulation dielectric layer 3. In some implementation structures, a thickness of the insulation dielectric layer 5 is thinner than a thickness of another insulation dielectric layer.

After the first electrode 101 and the channel layer 103 of the first transistor Tw are prepared in the insulation dielectric layer 2 and the insulation dielectric layer 5, when a groove is etched in the insulation dielectric layer 3, the channel layer 103 can be protected through the gate dielectric layer 105 and the insulation dielectric layer 5 that are stacked, to improve a product yield and ensure product performance.

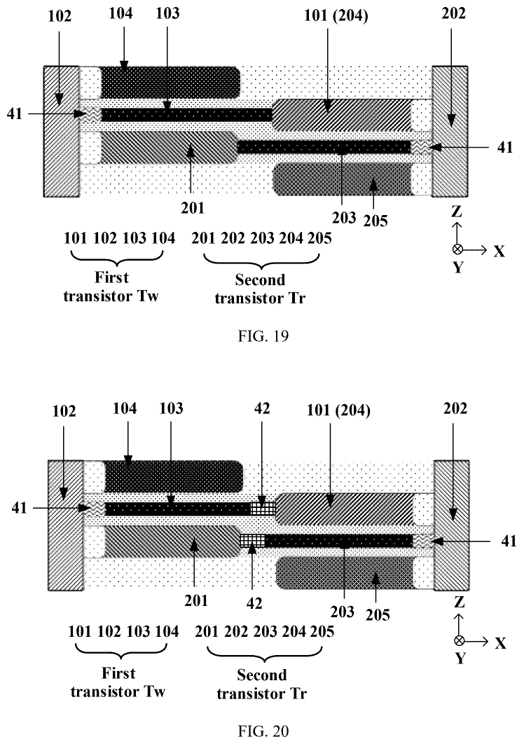

As shown in FIG. 19, like FIG. 16, FIG. 19 also shows a process structure of a memory cell obtained after the memory cell is cut in a direction perpendicular to the substrate. The structure shown in FIG. 19 differs from the structures shown in FIG. 9 and FIG. 16 in that, in the first transistor Tw, a contact transition layer 41 is disposed between interfaces in which the channel layer 103 is in ohmic contact with the second electrode 102; and in the second transistor Tr, a contact transition layer 41 is disposed between interfaces in which the channel layer 203 is in ohmic contact with the second electrode 202. The contact transition layer 41 can effectively reduce a resistance value between the electrode and the channel, and increase a current value of the channel.

FIG. 20 also shows a process structure of a memory cell obtained after the memory cell is cut in a direction perpendicular to the substrate. The memory cell shown in FIG. 20 differs from the memory cell shown in FIG. 19 in that, in the first transistor Tw, a contact transition layer 42 is disposed between interfaces in which the channel layer 103 is in ohmic contact with the first electrode 101; and in the second transistor Tr, a contact transition layer 42 is disposed between interfaces in which the channel layer 203 is in ohmic contact with the first electrode 201.

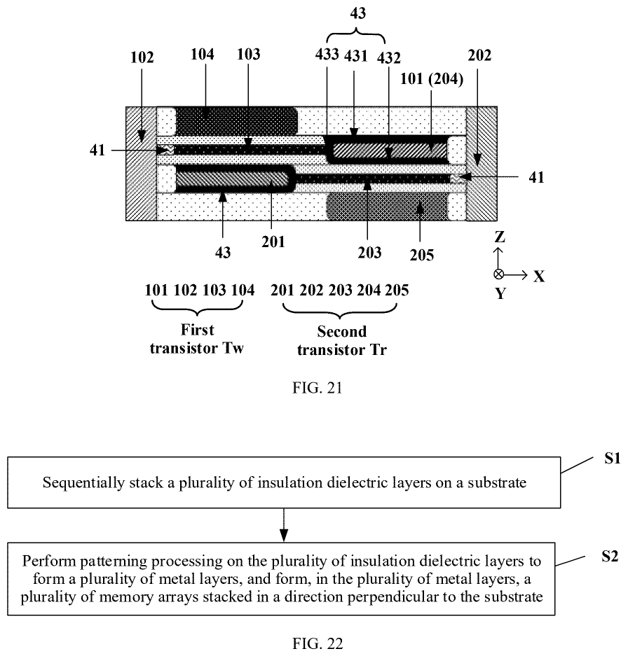

FIG. 21 also shows a process structure of a memory cell obtained after the memory cell is cut in a direction perpendicular to the substrate. Similar to the memory cell shown in FIG. 20, in the memory cell shown in FIG. 21, in the first transistor Tw, a contact transition layer 43 is disposed between interfaces in which the channel layer 103 is in ohmic contact with the first electrode 101; and in the second transistor Tr, a contact transition layer 43 is disposed between interfaces in which the channel layer 203 is in ohmic contact with the first electrode 201. The memory cell shown in FIG. 21 differs from the memory cell shown in FIG. 20 in that a process structure of the contact transition layer 43 in FIG. 21 is different from a process structure of the contact transition layer 42 in FIG. 20.

Both the contact transition layer 41 and the contact transition layer 42 in FIG. 20 are strip-shaped structures, and are stacked between the electrode and the channel layer. The contact transition layer 43 in FIG. 21 includes a first part 431, a second part 432, and a third part 433. The first part 431 and the second part 432 are parallel to the substrate, and the third part 433 is connected between the first part 431 and the second part 432, to form a structure having a concave cavity. The first electrode 101 or the first electrode 201 is disposed in the concave cavity, and the third part 433 is in contact with the channel layer 103 or the channel layer 203.

In the foregoing different implementations, the contact transition layer has a plurality of implementable structures.

For example, as shown in the contact transition layer 41 in FIG. 21, a metal layer may be disposed between interfaces in which the channel layer 103 is in ohmic contact with the second electrode 102, and the metal layer forms the contact transition layer 41. For the metal layer, some metal materials whose work functions are close to electron affinity of a semiconductor material channel need to be selected. For example, the metal materials may be TiN (titanium nitride), Ti (titanium), Au (gold), W (tungsten), and Mo (molybdenum), In—Ti—O (ITO, indium tin oxide), Ni (nickel), and the like.

For another example, as shown in the contact transition layer 41 in FIG. 21, an end that is of the channel layer 103 and that is close to the second electrode 102 may be heavily doped, to form a region whose doping concentration is higher than a doping concentration of the channel layer 103, and the heavily doped region forms the contact transition layer 41.

For still another example, as shown in the contact transition layer 43 in FIG. 21, a groove is etched in the insulation dielectric layer at which the first electrode 101 is located. The groove is filled with the first electrode 101. Before the first electrode 101 is filled, a metal layer is first deposited on an inner wall surface of the groove, the metal layer forms the contact transition layer 43, and then remaining space of the groove is filled with the first electrode 101, so that the first electrode 101 is coated in the contact transition layer 43 made of the metal layer.

For still another example, as shown in the contact transition layer 43 in FIG. 21, a groove is etched in an insulation dielectric layer at which the first electrode 101 is located. The groove is filled with the first electrode 101. Before the first electrode 101 is filled, a semiconductor material is first deposited on an inner wall surface of the groove, and then ion implantation is performed on the semiconductor material to form a heavily doped semiconductor layer. The heavily doped semiconductor layer forms the contact transition layer 43, and remaining space of the groove is filled with the first electrode 101, so that the first electrode 101 is coated in the contact transition layer 43.

The foregoing examples merely show that a heavily doped semiconductor layer may be formed through metal deposition or ion implantation, to obtain the contact transition layer. Certainly, a contact transition layer of another structure may alternatively be prepared through another process.

In the memory cell provided in the foregoing embodiment, the first transistor Tw, the second transistor Tr, the first electrode line, the second electrode line, the third electrode line, and the fourth electrode line may be made of a plurality of materials. The following provides some materials that may be selected.

Among the optional materials, the channel layer may be one or more of Si (silicon), poly-Si (p-Si, polycrystalline silicon), amorphous-Si (a-Si, amorphous silicon), In—Ga—Zn—O (IGZO, indium gallium zinc oxide) multicomponent compound, ZnO (zinc oxide), ITO (indium tin oxide), TiO₂ (titanium dioxide), MoS₂ (molybdenum disulfide), WS₂ (tungsten disulfide), graphene, black phosphorus and other semiconductor materials.

A material of the gate dielectric layer may be one or more of SiO₂ (silicon dioxide), Al₂O₃ (aluminum oxide), HfO₂ (hafnium dioxide), ZrO₂ (zirconium dioxide), TiO₂ (titanium dioxide), Y₂O₃ (yttrium trioxide), Si₃N₄ (silicon nitride), and other insulation materials.

A material of the insulation dielectric layer may be one or more of SiO₂ (silicon dioxide), Al₂O₃ (aluminum oxide), Si₃N₄ (silicon nitride) and other insulation materials.

Materials of the first electrode and the second electrode of either of the first transistor and the second transistor, the first electrode line, the second electrode line, the third electrode line, and the fourth electrode line are all conductive materials, for example, metal materials. In an optional implementation, materials of the first electrode and the second electrode may be one or more of TiN (titanium nitride), Ti (titanium), Au (gold), W (tungsten), Mo (molybdenum), In—Ti—O (ITO, indium tin oxide), Al (aluminum), Cu (copper), Ru (ruthenium), Ag (silver) and other conductive materials.

In addition, an embodiment of this disclosure further provides a method for forming a three-dimensional memory array. FIG. 22 is an example of a block diagram of a process of preparing a three-dimensional memory array.

Step S1: Sequentially stack a plurality of insulation dielectric layers on a substrate.

For example, when two memory arrays perpendicular to the substrate need to be prepared, at least eight insulation dielectric layers may be stacked on the substrate.

The insulation dielectric layer herein may be one or more of SiO₂ (silicon dioxide), Al₂O₃ (aluminum oxide), HfO₂ (hafnium dioxide), ZrO₂ (zirconium dioxide), TiO₂ (titanium dioxide), Y₂O₃ (yttrium trioxide), Si₃N₄ (silicon nitride), and other insulation materials.

Materials of two adjacent insulation dielectric layers may be the same or may be different.

Step S2: Perform patterning processing on the plurality of insulation dielectric layers to form a plurality of metal layers, and form, in the plurality of metal layers, a plurality of memory arrays stacked in a direction perpendicular to the substrate.

Each memory array includes a plurality of electrode lines and a plurality of memory cells. Each memory cell includes a first transistor and a second transistor. The second transistor is a dual-gate transistor. A first gate of the second transistor is electrically connected to a first electrode of the first transistor. Other electrodes of the first transistor and the second transistor are electrically connected to the plurality of electrode lines separately.

In a memory cell prepared by using the forming method, one gate of a second transistor used as a read transistor is electrically connected to a write transistor, and the other gate is electrically connected to a read word line. In this case, when the memory cell performs a read operation, no current flows through the gate of the read transistor, and a voltage drop (IR drop) of the read word line is mitigated.

The first electrode, a second electrode, and a channel layer of the first transistor are located at a first metal layer in the plurality of metal layers, and a gate of the first transistor is located at another metal layer.

A first electrode, a second electrode, and a channel layer of the second transistor are located at a second metal layer in the plurality of metal layers, the first gate and a second gate of the second transistor are located at other metal layers, and the first gate and the second gate are located at different metal layers.

One of a source and a drain is the first electrode, and the other of the source and the drain is the second electrode.

In other words, each film layer structure of the first transistor and each film layer

structure of the second transistor are integrated into the plurality of stacked insulation dielectric layers.

The following describes a specific process flow in step S1 and step S2 with reference to the accompanying drawings.

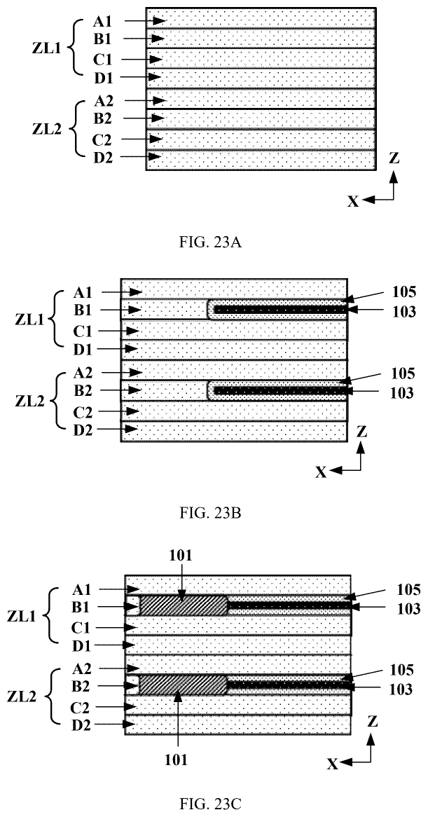

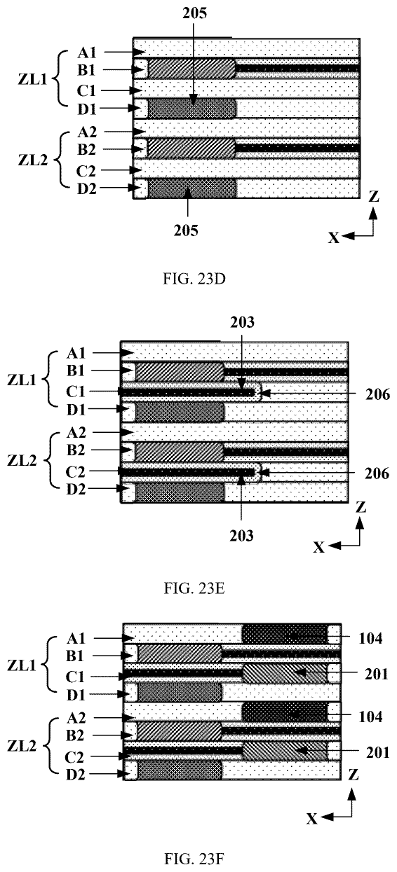

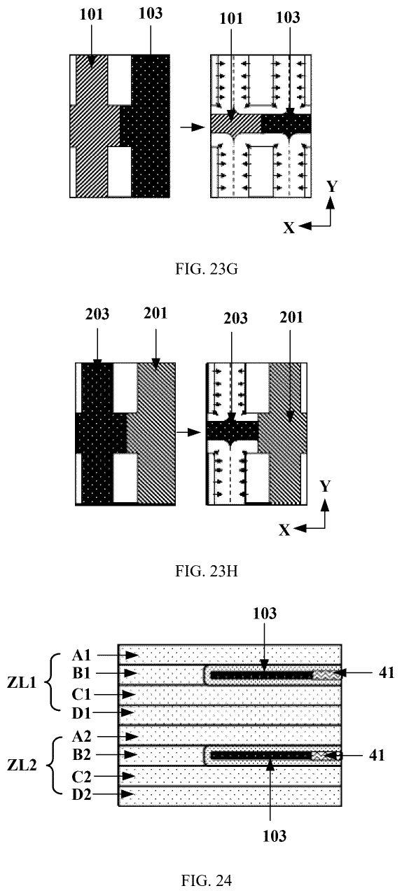

FIG. 23A to FIG. 23F each show a process structure obtained after each step is completed in a process of obtaining the three-dimensional memory array according to embodiments of this disclosure.

As shown in FIG. 23A, the plurality of insulation dielectric layers are sequentially stacked on the substrate. The plurality of insulation dielectric layers may be divided into a plurality of functional layers, and each functional layer may be used to prepare one memory array. For example, in FIG. 23A, an insulation dielectric layer A1, an insulation dielectric layer B1, an insulation dielectric layer M1, and an insulation dielectric layer D1 that are sequentially stacked are a functional layer, and may be used to prepare a memory array ZL1. An insulation dielectric layer A2, an insulation dielectric layer B2, an insulation dielectric layer M2, and an insulation dielectric layer D2 that are sequentially stacked are another functional layer, and may be used to prepare a memory array ZL2.

If more three-dimensional stacked memory arrays on the substrate need to be prepared, more insulation dielectric layers may be disposed based on FIG. 23A. One memory array may be prepared for every at least four adjacent insulation dielectric layers.

Materials of the foregoing insulation dielectric layers may be the same or may be different.

As shown in FIG. 23B, each of the insulation dielectric layer B1 and the insulation dielectric layer B2 is etched, then an etched hole is filled with a gate dielectric material, to prepare a gate dielectric layer 105 of the first transistor, and then the hole including the gate dielectric layer 105 is filled with a semiconductor material, to form the channel layer 103 of the first transistor.

That is, in a manufacturing process, insulation dielectric layers used to form channel layers of first transistors may be etched at the same time, to obtain channel layers of a plurality of three-dimensional stacked first transistors at the same time.

As shown in FIG. 23C, a side that is of each of the insulation dielectric layer B1 and the insulation dielectric layer B2 and that is away from the channel layer 103 is etched until the channel layer 103 is etched, and then an etched hole is filled with a conductive material (for example, metal), to prepare a second electrode 102 (one of the source and the drain) of the first transistor. A first electrode 101 of the first transistor may also be used as a first gate 204 of the second transistor.

As shown in FIG. 23D, each of the insulation dielectric layer D1 and the insulation dielectric layer D2 is etched, and then an etched hole is filled with a conductive material, to form a second gate 205 of the second transistor. In addition, the prepared second gate 205 of the second transistor is opposite to the first gate 204 of the second transistor.

As shown in FIG. 23E, each of the insulation dielectric layer M1 and the insulation dielectric layer M2 is etched, an etching location is located between the second gate 205 of the second transistor and the first gate 204 of the second transistor, and then an etched hole is filled with a gate medium material, to prepare a gate dielectric layer 206 of the second transistor. Then, a hole including the gate dielectric layer 206 is filled with a semiconductor material, to form a channel layer 203 of the second transistor.

In this way, in the prepared dual-gate second transistor, the first gate and the second gate are disposed on an upper side and a lower side of the channel layer.

As shown in FIG. 23F, each of the insulation dielectric layer A1 and the insulation dielectric layer A2 is etched, an etching location is opposite to the channel layer 103 of the first transistor, and an etched hole is filled with a conductive material, to prepare a first gate 104 of the first transistor.

In addition, each of the insulation dielectric layer M1 and the insulation dielectric layer M2 is etched, an etching location is opposite to the channel layer 103 of the first transistor, and an etched hole is filled with a conductive material, to prepare a first electrode 201 of the second transistor.

After the process step shown in FIG. 23F is completed, the first electrode 101 of the first transistor prepared in FIG. 23C extends in a direction (for example, a Y direction) parallel to the substrate, and the channel layer 103 of the first transistor prepared in FIG. 23C also extends in the direction (for example, the Y direction) parallel to the substrate. To separate the first electrode 101 of the first transistor from the channel layer 103 of the first transistor in different memory cells, as shown in FIG. 23G, a part between first electrodes 101 of first transistors in different memory cells needs to be etched, and a part between channel layers 103 of first transistors in different memory cells also needs to be etched, to obtain electrodes and channels that are independent of each other and that are in different memory cells.

Similarly, after the process step shown in FIG. 23F is completed, the channel layer 203 of the second transistor prepared in FIG. 23F extends in the direction (for example, the Y direction) parallel to the substrate. To separate channel layers 203 of second transistors in different memory cells, as shown in FIG. 23H, a part between the channel layers 203 of the second transistors in different memory cells needs to be etched, to obtain mutually independent channels in different memory cells.

Still refer to FIG. 23H. Because the first electrode 201 of the second transistor is grounded, first electrodes 201 of second transistors of different memory cells shown in FIG. 23H may be connected together.

It can be learned from the process steps shown in FIG. 23A to FIG. 23F that the plurality of memory arrays stacked on the substrate may be prepared through the plurality of stacked insulation dielectric layers, to implement three-dimensional stacking of the memory arrays, instead of a case in which one memory array layer is prepared and then another.

If a memory is prepared by stacking one memory array and then stacking another memory array, as storage density increases, a quantity of stacking layers also increases, and a requirement for photolithography alignment precision is also higher. If alignment precision between a lower-layer memory array structure and an upper-layer memory array structure is low, a read/write performance may be affected. However, according to the memory array preparation method provided in embodiments of this disclosure, a requirement on photolithography alignment precision is low, and no high challenge is posed to a process. In this way, a process can be simplified, process difficulty can be reduced, a product excellence rate can be improved, a read/write performance of the memory can be improved, and manufacturing costs of the memory are also reduced.

To reduce ohmic contact resistance between the electrode and the channel, after the process step shown in FIG. 23B is performed, the process step shown in FIG. 24 may be performed. After the channel layer 103 is prepared, an end of the channel layer 103 may be heavily doped through ion implantation, to form a contact transition layer 41 that can reduce resistance between the channel and the electrode.

Alternatively, in some other processes, after the channel layer 103 is prepared, a part of the end of the channel layer 103 is removed. For example, a metal layer may be formed through a deposition process, and the metal layer is used as the contact transition layer 41 that can reduce resistance between the channel and the electrode.

In the descriptions of this specification, the described specific features, structures, materials, or characteristics may be combined in a proper manner in any one or more of embodiments or examples.

The foregoing descriptions are merely specific implementations of this disclosure, but are not intended to limit the protection scope of this disclosure. Any variation or replacement readily figured out by a person skilled in the art within the technical scope disclosed in this disclosure shall fall within the protection scope of this disclosure. Therefore, the protection scope of this disclosure shall be subject to the protection scope of the claims.

1. A three-dimensional memory array, comprising:
a substrate; and
a plurality of memory arrays formed on the substrate, wherein the plurality of memory arrays are stacked in a direction perpendicular to the substrate;
wherein each memory array comprises a plurality of electrode lines and a plurality of memory cells, each memory cell comprises a first transistor and a second transistor, the second transistor is a dual-gate transistor, a first gate of the second transistor is electrically connected to a first electrode of the first transistor, and other electrodes of the first transistor and the second transistor are electrically connected to the plurality of electrode lines separately;
wherein the first electrode, a second electrode, and a channel layer of the first transistor are located at a first metal layer, and a gate of the first transistor is located at another metal layer;
wherein a first electrode, a second electrode, and a channel layer of the second transistor are located at a second metal layer, the first gate and a second gate of the second transistor are located at other metal layers, and the first gate and the second gate are located at different metal layers; and
wherein the first electrode is one of a source and a drain, and the second electrode is the other of the source and the drain.

2. The three-dimensional memory array according to claim 1, wherein the first gate of the second transistor is located at the first metal layer, and shares a same electrode with the first electrode of the first transistor.

3. The three-dimensional memory array according to claim 1, wherein the gate of the first transistor is located at a third metal layer, and the third metal layer is stacked on a side that is of the first metal layer and that is away from the second metal layer.

4. The three-dimensional memory array according to claim 3, wherein the gate of the first transistor is located on one side of the channel layer of the first transistor, and the first electrode of the second transistor is located on the other side of the channel layer of the first transistor; and
wherein an orthographic projection of the gate of the first transistor on the substrate at least partially overlaps an orthographic projection of the first electrode of the second transistor on the substrate.

5. The three-dimensional memory array according to claim 1, wherein the second gate of the second transistor is located at a fourth metal layer, and the fourth metal layer is stacked on a side that is of the second metal layer and that is away from the first metal layer.

6. The three-dimensional memory array according to claim 5, wherein the first gate of the second transistor is located on one side of the channel layer of the second transistor, and the second gate of the second transistor is located on the other side of the channel layer of the second transistor; and
wherein an orthographic projection of the first gate on the substrate at least partially overlaps an orthographic projection of the second gate on the substrate.

7. The three-dimensional memory array according to claim 1, wherein:
the plurality of electrode lines comprise a first electrode line and a second electrode line;
the first electrode line is electrically connected to the gate of the first transistor, and the second electrode line is electrically connected to the second gate of the second transistor;
the first electrode line and the gate of the first transistor are located at a same metal layer;
the second electrode line and the second gate of the second transistor are located at a same metal layer;
the first electrode line is parallel to the second electrode line;
the first electrode line is electrically connected to gates of two adjacent first transistors; and
the second electrode line is electrically connected to second gates of two adjacent second transistors.

8. The three-dimensional memory array according to claim 1, wherein:
the plurality of electrode lines comprise a ground lead;
the ground lead is located at the second metal layer; and
the ground lead is electrically connected to first electrodes of two adjacent second transistors.

9. The three-dimensional memory array according to claim 1, wherein:
the plurality of electrode lines comprise a third electrode line and a fourth electrode line;
the third electrode line is electrically connected to the second electrode of the first transistor, and the fourth electrode line is electrically connected to the second electrode of the second transistor;
both the third electrode line and the fourth electrode line extend in the direction perpendicular to the substrate;
the third electrode line is electrically connected to second electrodes of first transistors in two adjacent memory arrays; and
the fourth electrode line is electrically connected to second electrodes of second transistors in two adjacent memory arrays.

10. The three-dimensional memory array according to claim 1, wherein the first electrode of the second transistor is isolated from the channel layer of the first transistor through a dielectric layer.

11. The three-dimensional memory array according to claim 10, wherein the dielectric layer comprises a gate dielectric layer; and
wherein the gate dielectric layer is stacked between the channel layer of the first transistor and the first electrode of the second transistor.

12. The three-dimensional memory array according to claim 10, wherein the dielectric layer comprises a gate dielectric layer and an insulation dielectric layer;
wherein the gate dielectric layer and the insulation dielectric layer are stacked between the channel layer of the first transistor and the first electrode of the second transistor; and
wherein the insulation dielectric layer is closer to the first electrode of the second transistor than the gate dielectric layer.

13. The three-dimensional memory array according to claim 1, wherein in the first transistor or the second transistor, at least one of:
a contact transition layer is formed between interfaces in which the channel layer is in ohmic contact with the first electrode, or
a contact transition layer is formed between interfaces in which the channel layer is in ohmic contact with the second electrode.

14. The three-dimensional memory array according to claim 13, wherein:
a metal layer is formed between the channel layer and the first electrode, and the metal layer forms the contact transition layer; or
an end that is of the channel layer and that is close to the first electrode forms a doped conductive part, a doping concentration of the doped conductive part is greater than a doping concentration of the channel layer, and the doped conductive part forms the contact transition layer.

15. The three-dimensional memory array according to claim 13, wherein:
the contact transition layer formed between the channel layer and the first electrode comprises a first part, a second part, and a third part; and
both the first part and the second part are parallel to the substrate, the third part is connected to the first part and the second part to form a structure having a concave cavity, the first electrode is disposed in the concave cavity, and the third part is in contact with the channel layer.

16. The three-dimensional memory array according to claim 1, wherein the plurality of electrode lines and the plurality of memory cells are all formed on the substrate through a back end of line.

17. The three-dimensional memory array according to claim 1, wherein the three-dimensional memory array is a dynamic random access memory (DRAM) three-dimensional memory array.

18. A memory, comprising:
a three-dimensional memory array, wherein the three-dimensional memory array comprises:
a substrate;
a plurality of memory arrays formed on the substrate, wherein the plurality of memory arrays are stacked in a direction perpendicular to the substrate;
wherein each memory array comprises a plurality of electrode lines and a plurality of memory cells, each memory cell comprises a first transistor and a second transistor, the second transistor is a dual-gate transistor, a first gate of the second transistor is electrically connected to a first electrode of the first transistor, and other electrodes of the first transistor and the second transistor are electrically connected to the plurality of electrode lines separately;
wherein the first electrode, a second electrode, and a channel layer of the first transistor are located at a first metal layer, and a gate of the first transistor is located at another metal layer;
wherein a first electrode, a second electrode, and a channel layer of the second transistor are located at a second metal layer, the first gate and a second gate of the second transistor are located at other metal layers, and the first gate and the second gate are located at different metal layers; and
wherein the first electrode is one of a source and a drain, and the second electrode is the other of the source and the drain; and
a controller, wherein the controller is electrically connected to the three-dimensional memory array, and the controller is configured to control read/write of the three-dimensional memory array.

19. An electronic device, comprising:
at least one processor; and
at least one memory, wherein the at least one memory comprises:
a three-dimensional memory array, wherein the three-dimensional memory array comprises:
a substrate;
a plurality of memory arrays formed on the substrate, wherein the plurality of memory arrays are stacked in a direction perpendicular to the substrate;
wherein each memory array comprises a plurality of electrode lines and a plurality of memory cells, each memory cell comprises a first transistor and a second transistor, the second transistor is a dual-gate transistor, a first gate of the second transistor is electrically connected to a first electrode of the first transistor, and other electrodes of the first transistor and the second transistor are electrically connected to the plurality of electrode lines separately;
wherein the first electrode, a second electrode, and a channel layer of the first transistor are located at a first metal layer, and a gate of the first transistor is located at another metal layer;
wherein a first electrode, a second electrode, and a channel layer of the second transistor are located at a second metal layer, the first gate and a second gate of the second transistor are located at other metal layers, and the first gate and the second gate are located at different metal layers; and
wherein the first electrode is one of a source and a drain, and the second electrode is the other of the source and the drain; and
a controller, wherein the controller is electrically connected to the three-dimensional memory array, and the controller is configured to control read/write of the three-dimensional memory array; and
wherein the at least one processor is electrically connected to the at least one memory, and the at least one memory is configured to store data generated by the at least one processor.

20. The electronic device according to claim 19, wherein the first gate of the second transistor is located at the first metal layer, and shares a same electrode with the first electrode of the first transistor.
